(19) United States
(12) Patent Application Publication
(10) Pub. No.: US 2011/0214263 A1
(43) Pub. Date: Sep. 8, 2011

(54) METHOD OF MANUFACTURING PACKAGE, PACKAGE, PIEZOELECTRIC VIBRATOR, OSCILLATOR, ELECTRONIC APPARATUS, AND RADIO-CONTROLLED TIMEPIECE

(76) Inventors: Masashi Numata, Chiba-shi (JP); Hiroshi Higuchi, Yokkaichi-shi (JP)

(21) Appl. No.: 13/038,972

(22) Filed: Mar. 2, 2011

(30) Foreign Application Priority Data
Mar. 3, 2010 (JP) 2010-047186

(51) Int. Cl. H01L 41/22; B28B 11/00; B28B 7/34

(52) U.S. Cl. 29/25.35; 249/117; 249/134

(57) ABSTRACT

Provided are a package manufacturing method capable of hot-molding a substrate into a desired shape, and a package and a piezoelectric vibrator manufactured by the manufacturing method, and an oscillator, an electronic apparatus, and a radio-controlled timepiece each having the piezoelectric vibrator. A molding step is a step in which in a penetration hole forming step, through-holes are formed by pressing and heating a base substrate wafer with a through-hole forming mold having convex portions corresponding to the through-holes. The through-hole forming mold is formed of a material having an open porosity equal to or larger than 14%.

### RELATED APPLICATIONS

This application claims priority under 35 U.S.C. §119 to Japanese Patent Application No. 2010-047186 filed on Mar. 3, 2010, the entire content of which is hereby incorporated by reference.

### BACKGROUND OF THE INVENTION

1. Field of the Invention

The present invention relates to a method of manufacturing a package, a package and a piezoelectric vibrator manufactured by the manufacturing method, and an oscillator, an electronic apparatus, and a radio-controlled timepiece each having the piezoelectric vibrator.

2. Background Art

Recently, piezoelectric vibrators (packages) utilizing quartz or the like have been used in cellular phones and portable information terminals as the time source, the timing source of a control signal, a reference signal source, and the like. The piezoelectric vibrator of this type has been proposed in a variety of forms, and a surface mounted device (SMD)-type piezoelectric vibrator is one example thereof. The surface mounted device-type piezoelectric vibrator includes, for example, a base substrate and a lid substrate which are made of a glass material and bonded to each other, a cavity formed between the two substrates, and a piezoelectric vibrating reed (electronic component) accommodated in a state of being airtightly sealed in the cavity.

In such a piezoelectric vibrator, a configuration in which a penetration electrode is formed in a penetration hole formed in a base substrate, and a piezoelectric vibrating reed in a cavity is electrically connected to outer electrodes outside the cavity by the penetration electrode is known (for example, see JP-A-2002-124845).

As a method of forming the penetration electrode, a method which uses a metal pin made of a metal material is known. Specifically, first, a metal pin is inserted into the penetration hole formed in a base substrate, and a glass frit is inserted into the penetration hole. After that, the glass frit is baked so that the base substrate is integrated with the metal pin, thus blocking the penetration hole, and making the piezoelectric vibrating reed and the outer electrodes electrically connected. In this case, it is considered that the use of the metal pin as the penetration electrode enables the securing of stable conduction.

However, according to the method described above, since binders of the organic material included in the glass frit are removed by the baking, there is a case where a recess portion caused by a decrease in the volume is formed on the surface of the glass frit. Moreover, the recess portion on the glass frit may cause short-circuiting in a later step of forming an electrode film (an outer electrode or the like).

In recent years, a method of forming penetration electrodes by welding metal pins to penetration holes formed on the base substrate has been developed. In this method, first, a base substrate is heated and pressed with a penetration hole forming mold which is made of a carbon material (isotropic electrographite) or the like, whereby penetration holes through which metal pins are inserted are formed (primary molding). After that, the base substrate and metal pins are set in a welding mold made of a carbon material or the like in a state where the metal pins are inserted into the penetration holes, and the base substrate is pressed and heated (secondary molding). In this way, the base substrate is moved within the welding mold, whereby the gap between the metal pins and the penetration holes are blocked, and the base substrate is welded to the metal pins. In general, the primary molding is performed in a nitrogen atmosphere, and the secondary molding is performed in an air atmosphere.

However, the above-described method still has the following problems.

First, when the base substrate is heated, outgas is discharged into the mold from the base substrate. When the mold is filled with the outgas, the outgas cannot escape. Then, some outgas is unable to be discharged from the base substrate but remains in the base substrate as bubbles. As a result, the base substrate causes a mold collapsing (that is, a so-called bubble phenomenon occurs), and it is unable to maintain the base substrate in a desired shape.

In the piezoelectric vibrator, after forming the penetration electrodes in the base substrate, electrode films such as the outer electrodes for electrically connecting the penetration electrodes to the outside or the lead-out electrodes for electrically connecting the penetration electrodes and the piezoelectric vibrating reeds are formed using a photolithography technique, a sputtering method, or the like. Therefore, in order to secure conduction between the penetration electrodes and the electrode films, it is necessary to increase the positioning accuracy of the penetration electrodes (the positioning accuracy of the penetration holes or metal pins) on the base substrate.

### SUMMARY OF THE INVENTION

Therefore, an object of the present invention is to provide a package manufacturing method capable of hot-molding a substrate into a desired shape, and a package and a piezoelectric vibrator manufactured by the manufacturing method, and an oscillator, an electronic apparatus, and a radio-controlled timepiece each having the piezoelectric vibrator.

In order to solve the problems, the invention provides the following means.

According to an aspect of the present invention, there is provided a method of manufacturing a package which has a plurality of substrates made of a glass material and bonded to each other and a cavity formed at an inner side of the plurality of substrates and capable of sealing an electronic component, the method including a molding step of molding the substrate by pressing and heating the substrate with a shaping mold, in which the shaping mold is made of a material having an open porosity equal to or larger than 14%.

According to this configuration, since the shaping mold is made of a material having an open porosity equal to or larger than 14%, the outgas discharged from the substrate during the hot-molding enters into the open pores of the shaping mold. That is, the open pores of the shaping mold serve as the escape route for the outgas discharged from the substrate. Thus, it is possible to reduce the amount of remaining outgas in the substrate and to suppress the occurrence of the bubble phenomenon. Therefore, it is possible to suppress a mold collapsing of the substrate during the hot-molding and to maintain a desired shape of the substrate.

Here, the open porosity is the percentage (JIS R 1634) of a volume of open pores with respect to an apparent volume of a sample which is 1.

In the package manufacturing method, it is preferable that the shaping mold is made of a material having a thermal expansion coefficient equal to or larger than 4 ppm/° C.

According to this configuration, since the difference between the thermal expansion coefficient of the shaping mold and the thermal expansion coefficient of the substrate (generally, about 8.3 ppm/° C. in the case of a glass material) can be reduced, it is possible to suppress strain or the like occurring between the shaping mold and the substrate resulting from the heating during the molding step and to improve the positioning accuracy during the molding step. In this case, at the time of forming penetration electrodes, for example, the penetration electrodes can be disposed at a desired position on the substrate. As a result, it is possible to secure conduction between the penetration electrodes and electrode films such as outer electrodes or lead-out electrodes which are formed later.

In the package manufacturing method, it is preferable that the molding step is performed under an inert gas atmosphere, and the shaping mold is made of a material containing a carbon material as its main component.

According to this configuration, since a carbon material generally has a thermal expansion coefficient close to that of a glass material, as described above, it is possible to suppress strain or the like occurring between the shaping mold and the substrate resulting from the heating during the molding step and to improve the positioning accuracy during the molding step.

Moreover, by performing the molding step under the inert gas atmosphere, even when the shaping mold made of a carbon material is used, it is possible to suppress oxidation of the shaping mold. Thus, it is possible to suppress the increase in wetting of the shaping mold by the substrate and to maintain the demolding property of the shaping mold. Moreover, the durability of the shaping mold can be improved.

Furthermore, since the material containing a carbon material as its main component is relatively cheap, the shaping mold can be produced at a low cost. In addition, since the material containing a carbon material as its main component is easy to process, the shaping mold can be formed easily and with high accuracy using an NC machine or the like. Therefore, it is possible to secure the flatness of the processed surface of the shaping mold and to secure the flatness of the substrate molded so as to resemble the processed surface.

In the package manufacturing method, it is preferable that the molding step is performed under an air atmosphere, and the shaping mold is made of a material containing a boron nitride as its main component.

According to this configuration, since the material containing a boron nitride as its main component is superior in oxidation resistance, even when the molding step is performed under an air atmosphere, it is possible to suppress the increase in wetting of the shaping mold by the substrate and to suppress the oxidation of the shaping mold. In this way, as described above, it is possible to maintain the demolding property of the shaping mold. Moreover, the durability of the shaping mold can be improved, and the molding can be performed at a relatively high temperature.

In addition, since the material containing a boron nitride as its main component is superior in machine processability, it is possible to secure the flatness of the processed surface of the shaping mold and to secure the flatness of the substrate molded so as to resemble the processed surface.

In the package manufacturing method, it is preferable that the method includes a penetration electrode forming step of forming penetration electrodes making the inner side of the cavity and the outer side of the plurality of substrates conductive, and the penetration electrode forming step includes: a recess forming step of forming recess portions so as to extend in the thickness direction of a penetration electrode forming substrate among the plurality of substrates; and a core disposing step of inserting core portions made of a conductive material into the recess portions of the penetration electrode forming substrate, in which the molding step is a step in which in the recess forming step, the recess portions are formed by pressing and heating the penetration electrode forming substrate with the shaping mold having convex portions corresponding to the recess portions.

According to this configuration, as described above, since the occurrence of a bubble phenomenon or the like in the penetration electrode forming substrate can be suppressed, it is possible to maintain a desired shape of the penetration electrode forming substrate after the hot-molding.

In addition, when a shaping mold made of a material having a thermal expansion coefficient equal to larger than 4 ppm/° C. is used, it is possible to suppress the occurrence of strain between the shaping mold and the penetration electrode forming substrate. Thus, the penetration electrode forming substrate can be molded with higher accuracy. Moreover, the recess portions can be formed at desired positions with high accuracy. Furthermore, by inserting the core portions into the recess portions formed as described above, it is possible to dispose the penetration electrodes at desired positions with high accuracy.

In the package manufacturing method, it is preferable that the penetration electrode forming step includes, at the end of the core disposing step, a welding step of welding the penetration electrode forming substrate to the core portions, and the molding step is a step in which in the welding step, the penetration electrode forming substrate is welded to the core portions by pressing and heating the penetration electrode forming substrate with the shaping mold.

According to this configuration, as described above, since the occurrence of a bubble phenomenon or the like in the penetration electrode forming substrate can be suppressed, it is possible to maintain a desired shape of the penetration electrode forming substrate after the welding.

In addition, when a shaping mold made of a material having a thermal expansion coefficient equal to larger than 4 ppm/° C. is used, it is possible to suppress the occurrence of strain between the shaping mold and the penetration electrode forming substrate. Thus, the penetration electrode forming substrate can be molded with further higher accuracy. Moreover, since the stress applied from the shaping mold to the core portions due to the strain occurring between the shaping mold and the penetration electrode forming substrate can be decreased, it is possible to suppress the core portions in the penetration holes from being moved towards the shaping mold to be displaced from desired positions or tilted. As a result, since the positioning accuracy of the penetration electrodes on the penetration electrode forming substrate can be improved, it is possible to secure conduction between the penetration electrodes and electrode films such as outer electrodes or lead-out electrodes which are formed later.

In the package manufacturing method, it is preferable that the method includes a cavity forming step of forming the cavities on a cavity forming substrate among the plurality of substrates, and the molding step is a step in which in the cavity forming step, the cavities are formed by pressing and heating the cavity forming substrate with the shaping mold having convex portions corresponding to the cavities.

According to this configuration, as described above, since the occurrence of a bubble phenomenon or the like in the cavity forming substrate can be suppressed, it is possible to maintain a desired shape of the cavity forming substrate after the hot-molding.

In addition, when a shaping mold made of a material having a thermal expansion coefficient equal to larger than 4 ppm/° C. is used, since it is possible to suppress the occurrence of strain between the shaping mold and the cavity forming substrate, it is possible to form the cavities at desired positions with high accuracy. Therefore, it is possible to provide a package having excellent airtightness.

According to another aspect of the present invention, there is provided a package which is manufactured by the package manufacturing method according to the above aspect of the present invention.

According to this configuration, since the package is manufactured using the package manufacturing method of the above aspect of the present invention, it is possible to reduce the amount of remaining outgas in the substrate and to reduce the porosity of the package. Thus, a package having excellent airtightness can be provided. Moreover, since the positioning accuracy of the penetration electrodes can be improved, it is possible to provide a package in which the conduction between the inside and the outside of the cavity is excellent.

According to a still further aspect of the present invention, there is provided a piezoelectric vibrator in which a piezoelectric vibrating reed is airtightly sealed in the cavity of the package according to the above aspect of the present invention.

According to this configuration, since the piezoelectric vibrator includes the package having excellent airtightness, it is possible to provide a piezoelectric vibrator which has excellent vibration characteristics and high reliability.

According to a still further aspect of the present invention, there is provided an oscillator in which the piezoelectric vibrator according to the above aspect of the present invention is electrically connected to an integrated circuit as an oscillating piece.

According to a still further aspect of the present invention, there is provided an electronic apparatus in which the piezoelectric vibrator according to the above aspect of the present invention is electrically connected to a clock section.

According to a still further aspect of the present invention, there is provided a radio-controlled timepiece in which the piezoelectric vibrator according to the above aspect of the present invention is electrically connected to a filter section.

In the oscillator, electronic apparatus, and radio-controlled timepiece according to the above aspect of the present invention, since they have the above-described piezoelectric vibrator having excellent vibration characteristics and high reliability, it is possible to provide products having excellent vibration characteristics and high reliability similarly to the piezoelectric vibrator.

According to the package manufacturing method and the package of the above aspects of the present invention, since the shaping mold is made of a material having an open porosity equal to or larger than 14%, it is possible to hot-mold the substrate into a desired shape. Therefore, it is possible to provide a package having excellent airtightness and excellent conduction between the inside and the outside of the cavity.

According to the piezoelectric vibrator according to the above aspect of the present invention, since it includes the package according to the above aspect of the present invention, it is possible to provide a piezoelectric vibrator which has excellent vibration characteristics and high reliability.

According to the oscillator, electronic apparatus, and radio-controlled timepiece according to the above aspect of the present invention, since they have the above-described piezoelectric vibrator, it is possible to provide products having excellent vibration characteristics and high reliability similarly to the piezoelectric vibrator.

### BRIEF DESCRIPTION OF THE DRAWINGS

FIG. 1 is a perspective view showing an external appearance of a piezoelectric vibrator according to an embodiment of the present invention.

FIG. 2 is a top view showing a state where a lid substrate of the piezoelectric vibrator is removed.

FIG. 3 is a side sectional view of the piezoelectric vibrator taken along the line A-A in FIG. 2.

FIG. 4 is an exploded perspective view of the piezoelectric vibrator.

FIG. 5 is a top view of a piezoelectric vibrating reed.

FIG. 6 is a bottom view of the piezoelectric vibrating reed.

FIG. 7 is a sectional view taken along the line B-B in FIG. 5.

FIG. 8 is a perspective view of a rivet member used when manufacturing the piezoelectric vibrator shown in FIG. 1.

FIG. 9 is a flowchart of the manufacturing method of a piezoelectric vibrator according to a first embodiment.

FIG. 10 is an exploded perspective view of a wafer assembly.

FIG. 11 is a perspective view showing a state where a through-hole is formed in a base substrate wafer serving as a base substrate provided in the piezoelectric vibrator shown in FIG. 1.

FIGS. 12A and 12B are cross-sectional views of a base substrate wafer according to the first embodiment, illustrating a penetration hole forming step.

FIGS. 13A to 13D are cross-sectional views of the base substrate wafer according to the first embodiment, illustrating a core portion insertion step, a welding step, and a polishing step.

FIG. 14 is a top-view picture of a sample wafer showing a state where a bubble phenomenon occurs.

FIG. 15 is a side sectional view of a piezoelectric vibrator according to a second embodiment, taken along the line A-A in FIG. 2.

FIG. 16 is a perspective view of a rivet member according to the second embodiment.

FIG. 17 is a flowchart of the manufacturing method of a piezoelectric vibrator according to the second embodiment.

FIGS. 18A and 18B are cross-sectional views of a base substrate wafer according to the second embodiment, illustrating a recess forming step.

FIGS. 19A to 19D are cross-sectional views of the base substrate wafer according to the second embodiment, illustrating a core portion insertion step and a welding step.

FIG. 20 is a view showing the configuration of an oscillator according to an embodiment of the present invention.

FIG. 21 is a view showing the configuration of an electronic apparatus according to an embodiment of the present invention.

FIG. 22 is a view showing the configuration of a radio-controlled timepiece according to an embodiment of the present invention.

FIGS. 23A and 23B are cross-sectional views of a lid substrate wafer, illustrating another method of a cavity forming step.

### DETAILED DESCRIPTION OF THE PREFERRED EMBODIMENTS

Hereinafter, an embodiment of the present invention will be described with reference to the drawings.

### First Embodiment

### Piezoelectric Vibrator

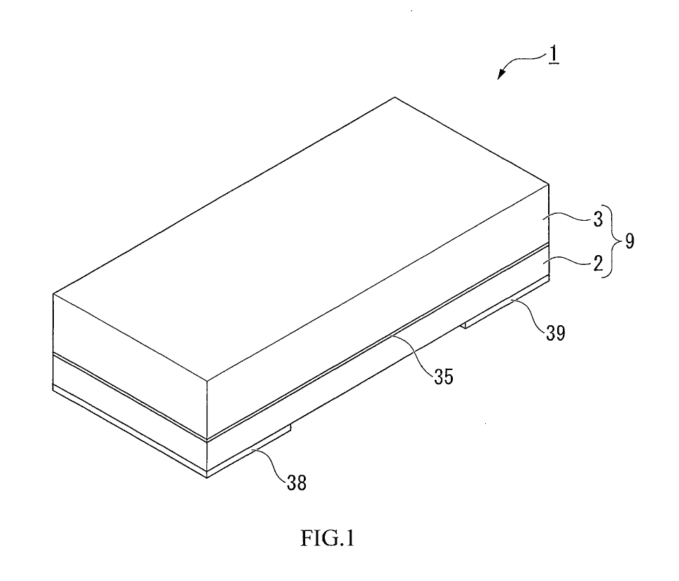

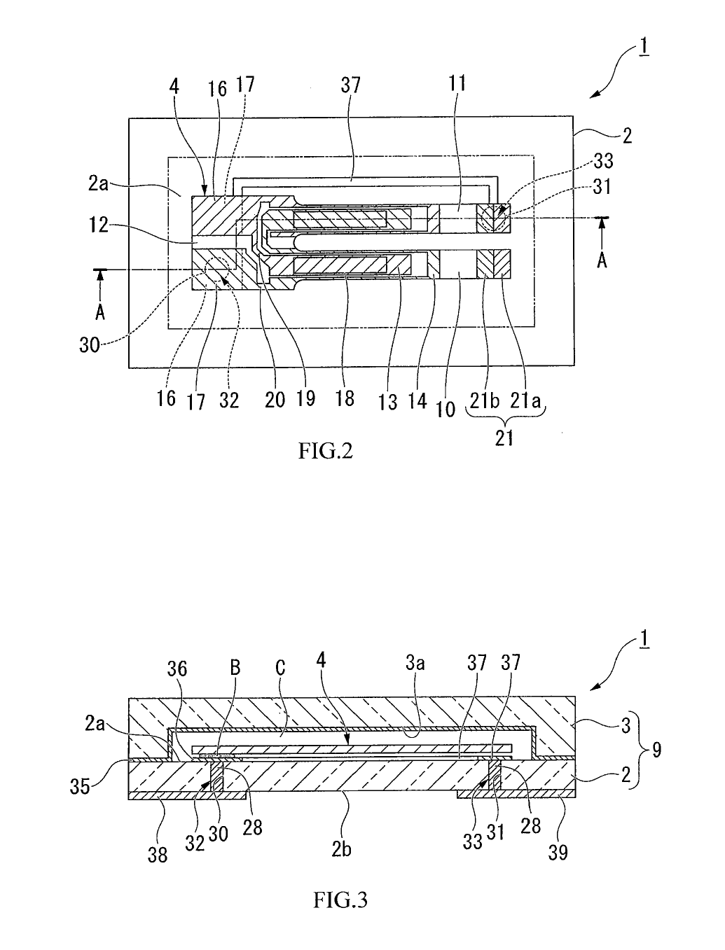

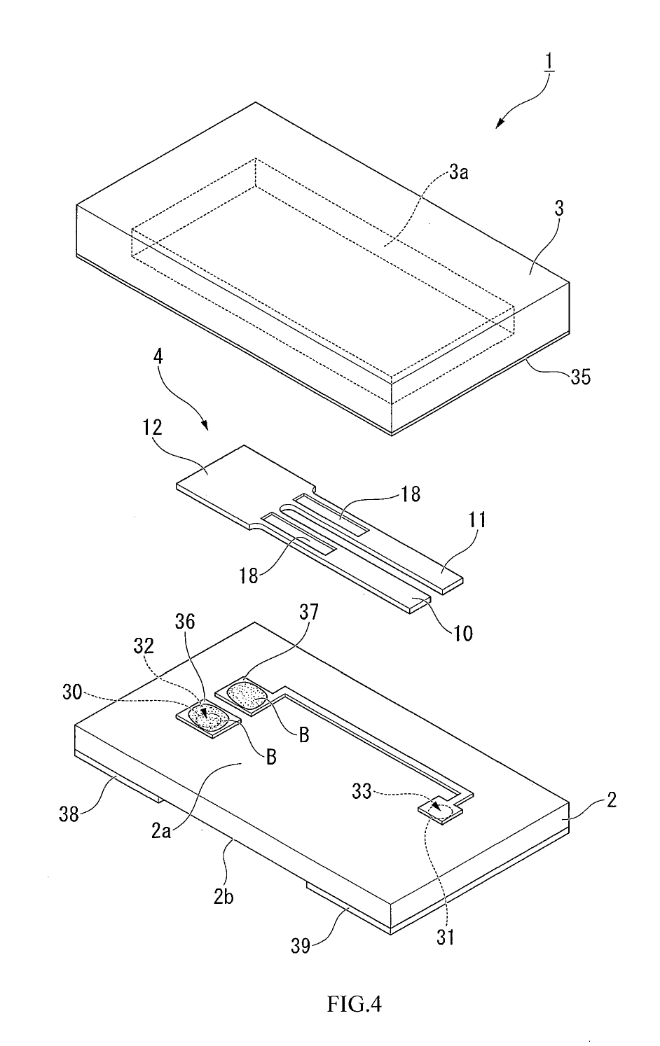

Next, a piezoelectric vibrator according to an embodiment of the present invention will be described with reference to the drawings. FIG. 1 is a perspective view showing an external appearance of a piezoelectric vibrator according to an embodiment of the present invention. FIG. 2 is a top view showing a state where a lid substrate of the piezoelectric vibrator is removed. FIG. 3 is a side sectional view of the piezoelectric vibrator taken along the line A-A in FIG. 2. FIG. 4 is an exploded perspective view of the piezoelectric vibrator. In FIG. 4, for better understanding of the drawings, illustrations of the excitation electrode 15, extraction electrodes 19 and 20, mount electrodes 16 and 17, and weight metal film 21 of the piezoelectric vibrating reed 4, which will be described later, are omitted.

As shown in FIGS. 1 to 4, a piezoelectric vibrator 1 according to the present embodiment is a surface mounted device-type piezoelectric vibrator 1 including: a package 9 having a base substrate 2 and a lid substrate 3 which are anodically bonded by a bonding film 35; and a piezoelectric vibrating reed 4 which is accommodated in a cavity C of the package 9.

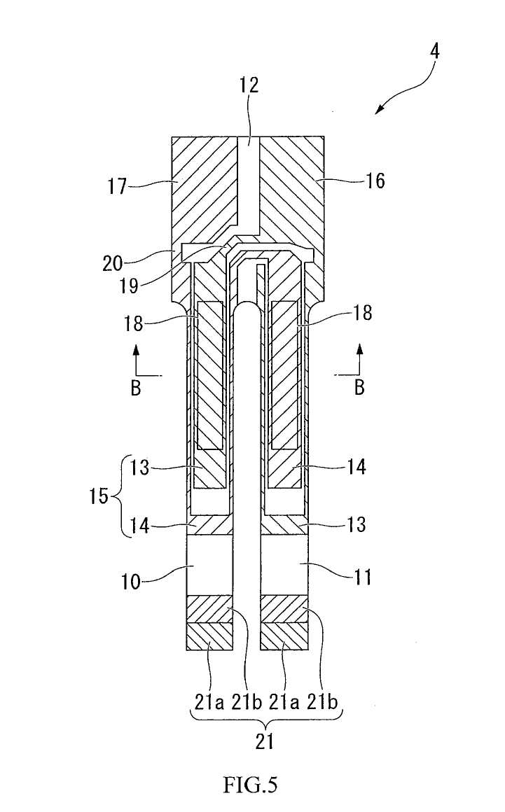

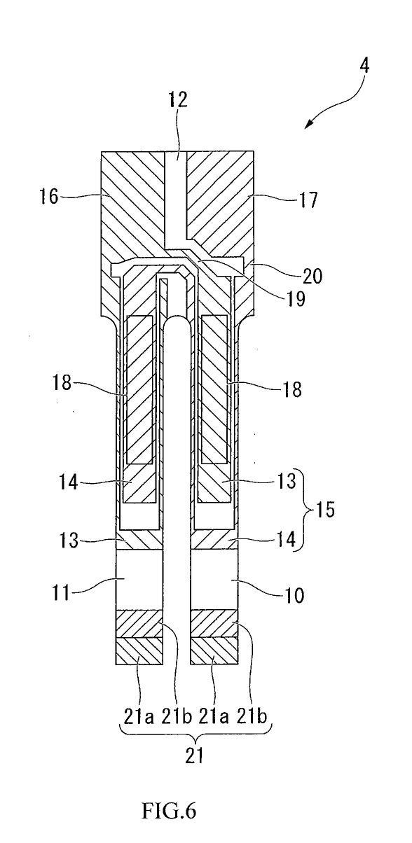

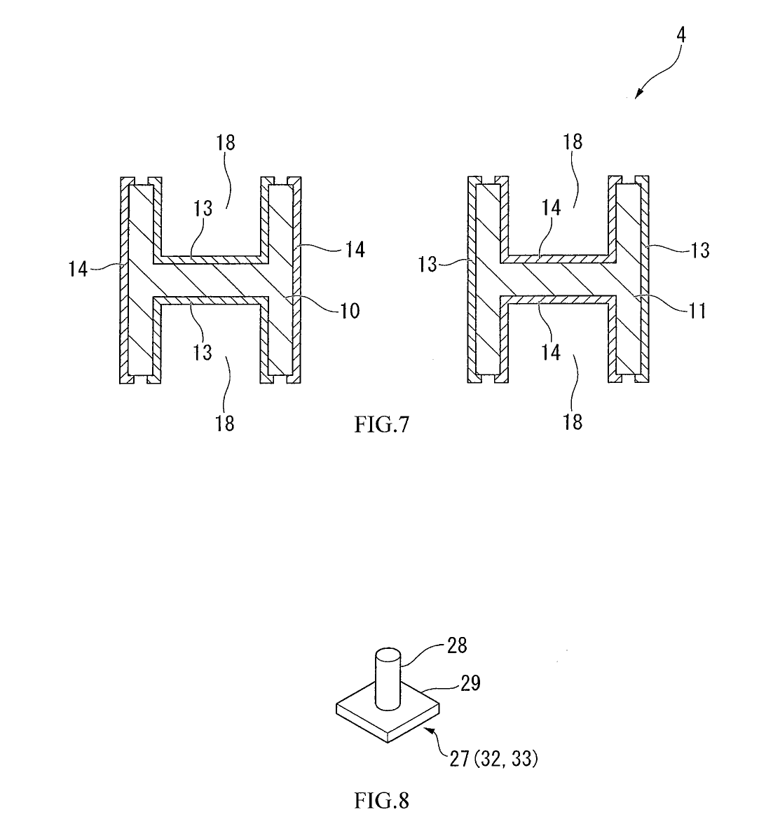

FIG. 5 is a top view of the piezoelectric vibrating reed, FIG. 6 is a bottom view, and FIG. 7 is a sectional view taken along the line B-B in FIG. 5.

As shown in FIGS. 5 to 7, the piezoelectric vibrating reed 4 is a tuning-fork type vibrating reed which is made of a piezoelectric material such as crystal, lithium tantalate, or lithium niobate and is configured to vibrate when a predetermined voltage is applied thereto. The piezoelectric vibrating reed 4 includes: a pair of vibrating arms 10 and 11 disposed in parallel to each other; a base portion 12 to which the base end sides of the pair of vibrating arms 10 and 11 are integrally fixed; groove portions 18 which are formed on both principal surfaces of the pair of vibrating arms 10 and 11. The groove portions 18 are formed so as to extend from the base end sides of the vibrating arms 10 and 11 along the longitudinal direction of the vibrating arms 10 and 11 up to approximately the middle portions thereof.

In addition, the piezoelectric vibrating reed 4 of the present embodiment includes: an excitation electrode 15 which is formed on the outer surfaces of the pair of vibrating arms 10 and 11 so as to allow the pair of vibrating arms 10 and 11 to vibrate and includes a first excitation electrode 13 and a second excitation electrode 14; and mount electrodes 16 and 17 which are electrically connected to the first excitation electrode 13 and the second excitation electrode 14, respectively. The excitation electrode 15, mount electrodes 16 and 17, and extraction electrodes 19 and 20 are formed by a coating of a conductive film of chromium (Cr), nickel (Ni), aluminum (Al), and titanium (Ti), for example.

The excitation electrode 15 is an electrode that allows the pair of vibrating arms 10 and 11 to vibrate at a predetermined resonance frequency in a direction moving closer to or away from each other. The first excitation electrode 13 and second excitation electrode 14 that constitute the excitation electrode 15 are patterned and formed on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11. Moreover, the first excitation electrode 13 and the second excitation electrode 14 are electrically connected to the mount electrodes 16 and 17 via the extraction electrodes 19 and 20, respectively, on both principal surfaces of the base portion 12.

Furthermore, the tip ends of the pair of the vibrating arms 10 and 11 are coated with a weight metal film 21 for adjustment of the vibration states (tuning the frequency) of the pair of the vibrating arms 10 and 11 in a manner such as to vibrate within a predetermined frequency range. The weight metal film 21 is divided into a rough tuning film 21a used for tuning the frequency roughly and a fine tuning film 21b used for tuning the frequency finely.

As shown in FIGS. 1, 3, and 4, the lid substrate 3 is a substrate that can be anodically bonded and that is made of a glass material, for example, soda-lime glass, and is formed in a substrate-like form. On a bonding surface side of the lid substrate 3 to be bonded to the base substrate 2, a recess portion 3a for a cavity C is formed in which the piezoelectric vibrating reed 4 is accommodated.

A bonding film 35 for anodic bonding is formed on the entire surface on the bonding surface side of the lid substrate 3 to be bonded to the base substrate 2. That is to say, the bonding film 35 is formed in a frame region at the periphery of the recess portion 3a in addition to the entire inner surface of the recess portion 3a. Although the bonding film 35 of the present embodiment is made of a Si film, the bonding film 35 may be made of Al. In addition, as the bonding film, a Si bulk material whose resistance value is reduced by doping or the like may be used. As will be described later, the bonding film 35 and the base substrate 2 are anodically bonded, whereby the cavity C is vacuum-sealed.

The base substrate 2 is a substrate that is made of a glass material, for example, soda-lime glass, and is formed in an approximately substrate-like form having the same outer shape as the lid substrate 3 as shown in FIGS. 1 to 4.

On an upper surface 2a side (a bonding surface side to be bonded to the lid substrate 3) of the base substrate 2, a pair of lead-out electrodes 36 and 37 is patterned as shown in FIGS. 1 to 4. The lead-out electrodes 36 and 37 are formed by a laminated structure of a lower Cr film and an upper Au film, for example.

As shown in FIGS. 3 and 4, the mount electrodes 16 and 17 of the above-described piezoelectric vibrating reed 4 are bump-bonded to the surfaces of the lead-out electrodes 36 and 37 via bumps B made of gold or the like. The piezoelectric vibrating reed 4 is bonded in a state where the vibrating arms 10 and 11 are floated from the upper surface 2a of the base substrate 2.

In addition, a pair of penetration electrodes 32 and 33 is formed on the base substrate 2 so as to penetrate through the base substrate 2. The penetration electrodes 32 and 33 are formed by arranging core portions 28 made of a conductive metallic material in the through-holes 30 and 31, and stable electrical conduction is secured by the core portions 28. One penetration electrode 32 is formed right below one lead-out electrode 36. The other penetration electrode 33 is formed in the vicinity of a tip end of the vibrating arm 11 and is connected to the other lead-out electrode 37 via a lead-out wiring.

The core portions 28 are fixed to the base substrate 2 by welding, and the core portions 28 completely block the through-holes 30 and 31, thus maintaining the airtightness of the cavity C. The core portions 28 are conductive cylindrical metallic core materials, for example, made of kovar and Fe—Ni alloys (42 alloy), whose thermal expansion coefficients are close to (preferably, equal to or lower than) that of the glass material of the base substrate 2, and have a shape which has flat ends and the same thickness as the base substrate 2.

FIG. 8 is a perspective view of a rivet member.

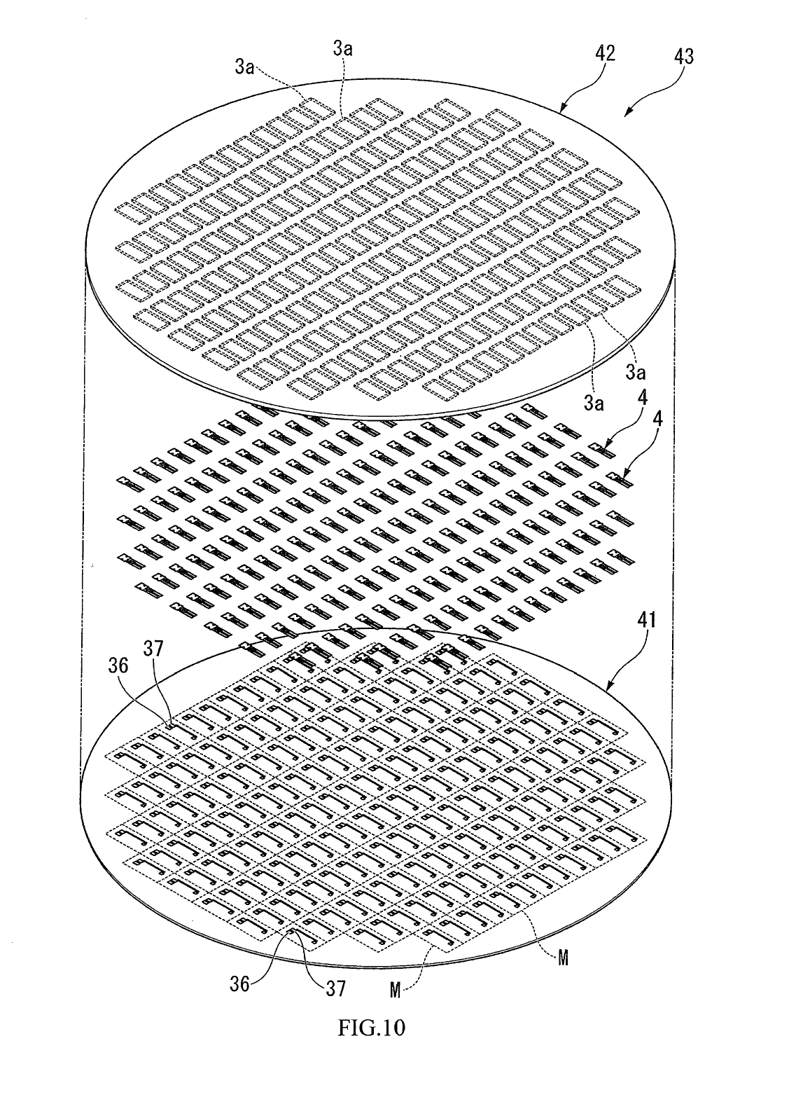

When the penetration electrodes 32 and 33 are formed as a finished product, as described above, the core portion 28 has a truncated conical shape and has the same thickness as the base substrate 2. However, in the course of the manufacturing process, as shown in FIG. 8, the core portion 28 forms a rivet member 27 together with a planar base portion 29 which is connected to one end thereof. That is, the core portion 28 is supported so that the extension direction thereof is identical to the thickness direction of the base portion 29. Moreover, the thickness (height) of the core portion 28 is smaller than the thickness of a base substrate wafer 41 (see FIG. 10) later serving as the base substrate 2.

The tip end of the core portion 28 protruding from the base portion 29 and the base substrate wafer 41 is polished and removed in the course of the manufacturing process. In addition, on a lower surface 2b of the base substrate 2, a pair of outer electrodes 38 and 39 is formed as shown in FIGS. 1, 3, and 4. The pair of outer electrodes 38 and 39 is formed at both ends in the longitudinal direction of the base substrate 2 and is electrically connected to the pair of penetration electrodes 32 and 33.

When the piezoelectric vibrator 1 configured in this way is operated, a predetermined drive voltage is applied between the outer electrodes 38 and 39 formed on the base substrate 2. By doing so, current flows from the one outer electrode 38 to the first excitation electrode 13 of the piezoelectric vibrating reed 4 through the one penetration electrode 32 and the one lead-out electrode 36. Moreover, current flows from the other outer electrode 39 to the second excitation electrode 14 of the piezoelectric vibrating reed 4 through the other penetration electrode 33 and the other lead-out electrode 37. In this way, current can be made to flow to the excitation electrode 15 including the first and second excitation electrodes 13 and 14 of the piezoelectric vibrating reed 4, and the pair of vibrating arms 10 and 11 is allowed to vibrate at a predetermined frequency in a direction moving closer to or away from each other. The vibration of the pair of vibrating arms 10 and 11 can be used as the time source, the timing source of a control signal, the reference signal source, and the like.

### Manufacturing Method of Piezoelectric Vibrator

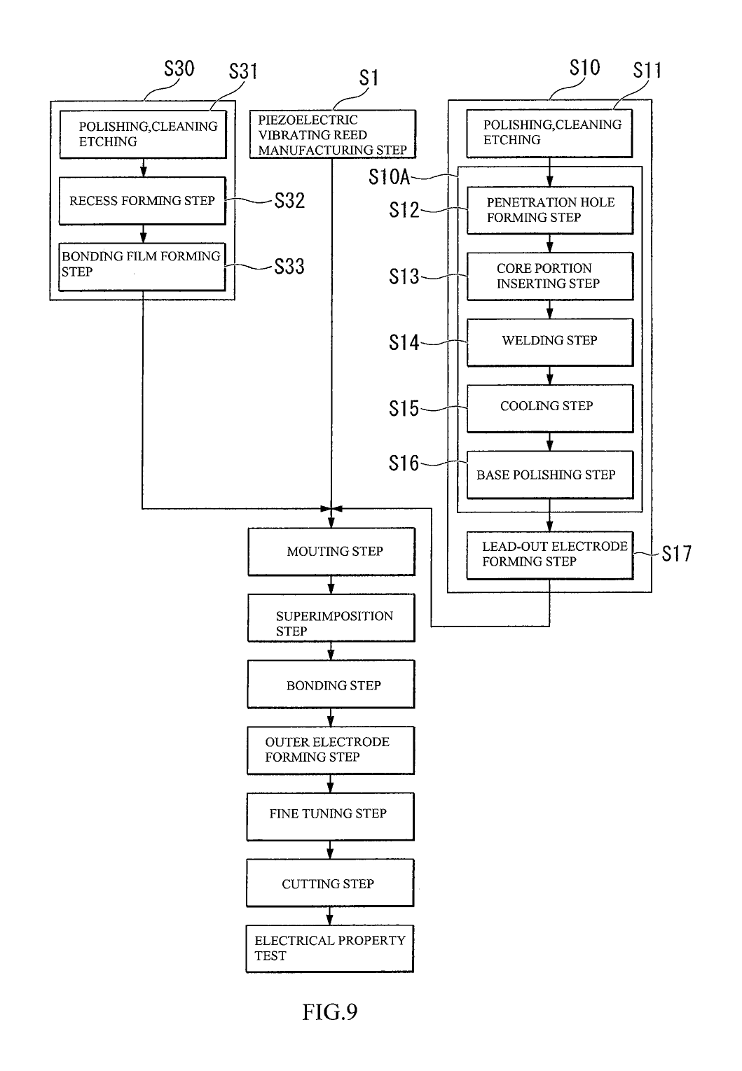

Next, the manufacturing method of the piezoelectric vibrator according to the present embodiment will be described. FIG. 9 is a flowchart of the manufacturing method of the piezoelectric vibrator according to the present embodiment. FIG. 10 is an exploded perspective view of a wafer assembly. In the following, a method for manufacturing a plurality of piezoelectric vibrators 1 at one time by enclosing a plurality of piezoelectric vibrating reeds 4 between a base substrate wafer (penetration electrode forming substrate) 41 and a lid substrate wafer (cavity forming substrate) 42 to form a wafer assembly 43 and cutting the wafer assembly 43 will be described. The dotted line M shown in the respective figures starting with FIG. 10 is a cutting line along which a cutting step performed later is achieved.

The manufacturing method of the piezoelectric vibrator according to the present embodiment mainly includes a piezoelectric vibrating reed manufacturing step (S1), a base substrate wafer manufacturing step (S10), and a lid substrate wafer manufacturing step (S30). Among the steps, the piezoelectric vibrating reed manufacturing step (S1), the base substrate wafer manufacturing step (S10), and the lid substrate wafer manufacturing step (S30) can be performed in parallel.

In the piezoelectric vibrating reed manufacturing step (S1), the piezoelectric vibrating reed 4 shown in FIGS. 5 to 7 is manufactured. Specifically, first, a rough crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured. Subsequently, rough tuning of the resonance frequency of the piezoelectric vibrating reed 4 is performed. This rough tuning is achieved by irradiating the rough tuning film 21a of the weight metal film 21 with a laser beam to evaporate in part the rough tuning film 21a, thus changing the weight of the vibrating arms 10 and 11.

Subsequently, a step of manufacturing the base substrate wafer 41 later serving as the base substrate 2 is performed (S10). First, the base substrate wafer 41 as shown in FIGS. 10 and 11 is formed. Specifically, soda-lime glass is polished to a predetermined thickness and cleaned, and then, the affected uppermost layer is removed by etching or the like (S11). FIG. 11 is a perspective view showing a part of the base substrate wafer 41, and the base substrate wafer 41 actually has an approximately disk shape (see FIG. 10). Moreover, the through-holes 30 and 31 in FIG. 11 are formed in a later step of forming the penetration electrodes 32 and 33 in the base substrate wafer 41.

### Penetration Electrode Forming Step

Subsequently, a penetration electrode forming step of forming the penetration electrodes 32 and 33 on the base substrate wafer 41 is performed (S10A).

### Penetration Hole Forming Step

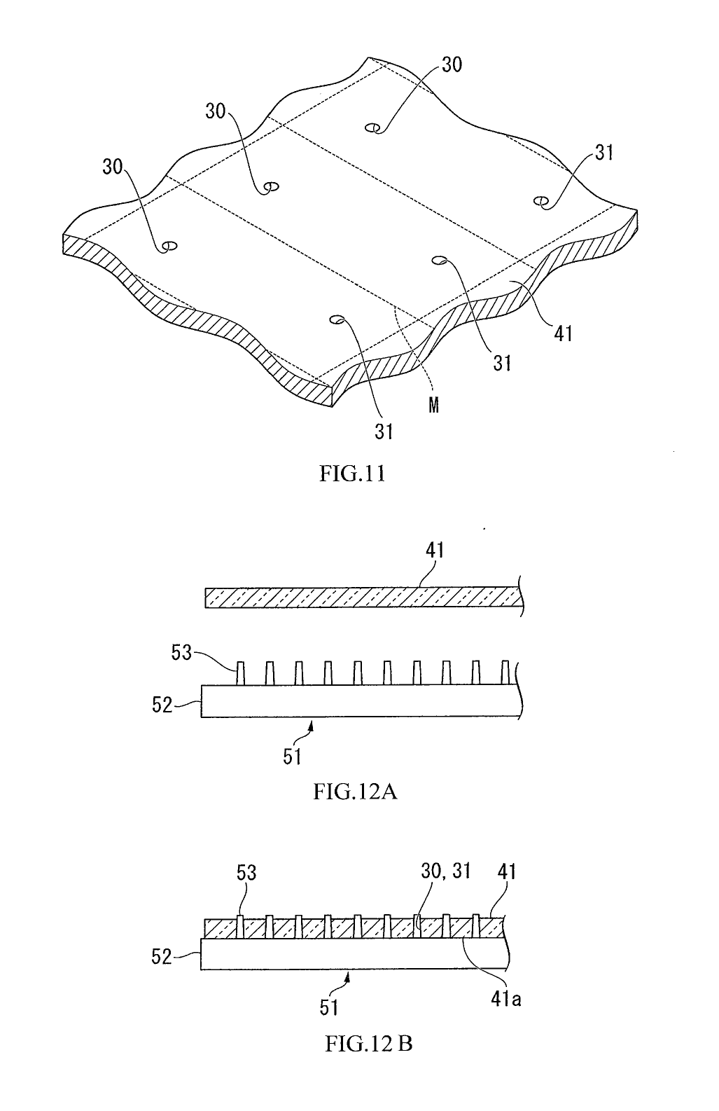

First, through-holes (recess portions) 30 and 31 are formed so as to penetrate through the base substrate wafer 41 (S12). FIGS. 12A and 12B are cross-sectional views of the base substrate wafer, illustrating the penetration hole forming step (recess forming step). In this specification, the recess portions also include the through-holes 30 and 31 and the like which penetrate through the base substrate wafer 41 in the thickness direction thereof and the portions which are recessed from the surface of the base substrate wafer 41.

The forming of the through-holes 30 and 31 is performed by pressing and heating the base substrate wafer 41 with a through-hole forming mold (shaping mold) 51 made of a carbon material and having a planar portion 52 and convex portions 53 formed on one surface of the planar portion 52 as shown in FIGS. 12A and 12B.

The planar portion 52 is a flat member which makes contact with the surface of the base substrate wafer 41 when pressing the base substrate wafer 41.

The convex portions 53 are members which penetrate through the base substrate wafer 41 to form the through-holes 30 and 31 when pressing the base substrate wafer 41. The convex portions 53 have a tapered side surface for mold removal on the side surface thereof, and the shapes of the convex portions 53 are transferred to the through-holes 30 and 31. At that time, the through-holes 30 and 31 have an inner diameter which is larger by about 20 to 30 μm than the diameter of the core portions 28. The base substrate wafer 41 is welded to the core portions 28 in a later manufacturing step, whereby the through-holes 30 and 31 are closed by the core portions 28.

In the penetration hole forming step (S12), first, as shown in FIG. 12A, the through-hole forming mold 51 is placed with the convex portions 53 positioned on the upper side (the upper side in FIG. 12A), and the base substrate wafer 41 is placed thereon. This assembly is placed in a heating furnace maintained under an inert gas atmosphere (nitrogen atmosphere) with pressure applied in a high temperature state of about 900° C., whereby the convex portions 53 penetrate through the base substrate wafer 41.

Subsequently, the base substrate wafer 41 is cooled gradually while decreasing the temperature.

As described above, in the penetration hole forming step (S12), although the through-hole forming mold 51 made of a carbon material is used, since the heating furnace is maintained under the inert gas atmosphere (nitrogen atmosphere), it is possible to suppress the oxidation of the through-hole forming mold 51 and to improve the durability of the through-hole forming mold 51. In this case, temperature of the heating furnace can be elevated to a maximum temperature of about 1000° C. Moreover, since it is possible to suppress the wetting property resulting from the oxidation of the through-hole forming mold 51, it is possible to maintain the demolding property of the through-hole forming mold 51 from the base substrate wafer 41. Although not shown in the drawings, a receiving mold is disposed above the base substrate wafer 41 so that the base substrate wafer 41 is pinched between the through-hole forming mold 51 and the receiving mold. The receiving mold receives the pressure applied from the through-hole forming mold 51.

The through-hole forming mold 51 of the present embodiment is preferably formed using a material of which the open porosity is equal to or larger than 14% and the thermal expansion coefficient is equal to or larger than 4 ppm/° C.

By forming the through-hole forming mold 51 using the material having an open porosity equal to or larger than 14%, the outgas discharged from the base substrate wafer 41 during the hot-molding enters into the open pores of the through-hole forming mold 51. That is, the open pores of the through-hole forming mold 51 serve as the escape route for the outgas discharged from the base substrate wafer 41. Thus, it is possible to reduce the amount of remaining outgas in the base substrate wafer 41 and to suppress the occurrence of the bubble phenomenon. Therefore, it is possible to suppress a mold collapsing of the base substrate wafer 41 after the hot-molding and to maintain a desired disk shape of the base substrate wafer 41.

During the demolding, since the gas present in the pores of the through-hole forming mold 51 enters into the gap between the through-hole forming mold 51 and the base substrate wafer 41, the base substrate wafer 41 after the hot-molding rarely adheres to the through-hole forming mold 51, and the demolding property of the through-hole forming mold 51 can be improved. Therefore, it is possible to prevent breaking and the like of the base substrate wafer 41 and improve the manufacturing efficiency. Here, the open porosity is the percentage (JIS R 1634) of a volume of open pores with respect to an apparent volume of a sample (the through-hole forming mold 51) which is 1.

Furthermore, by forming the through-hole forming mold 51 using the material having a thermal expansion coefficient equal to or larger than 4 ppm/° C., it is possible to reduce the difference between the thermal expansion coefficient of the through-hole forming mold 51 and the thermal expansion coefficient of the base substrate wafer (generally, about 8.3 ppm/° C.). Thus, it is possible to suppress strain occurring between the through-hole forming mold 51 and the base substrate wafer 41 resulting from the heating. In this way, it is possible to form the base substrate wafer 41 to a desired thickness and to an outer diameter with high accuracy. Moreover, the convex portions 53 can be disposed at desired positions on the base substrate wafer 41, and the positioning accuracy of the through-holes 30 and 31 can be secured.

As a material satisfying such a condition, the through-hole forming mold 51 of the present embodiment is made of a carbon material as described above. Furthermore, since the material containing a carbon material as its main component is relatively cheap, the through-hole forming mold 51 can be produced at a low cost. In addition, since the material containing a carbon material as its main component is easy to process, the through-hole forming mold 51 can be formed easily and with high accuracy using an NC machine or the like. Therefore, it is possible to secure the flatness (for example, within 30 μm) of the processed surface of the through-hole forming mold 51 and to secure the flatness of the base substrate wafer 41 molded so as to resemble the processed surface.

### Core Portion Insertion Step

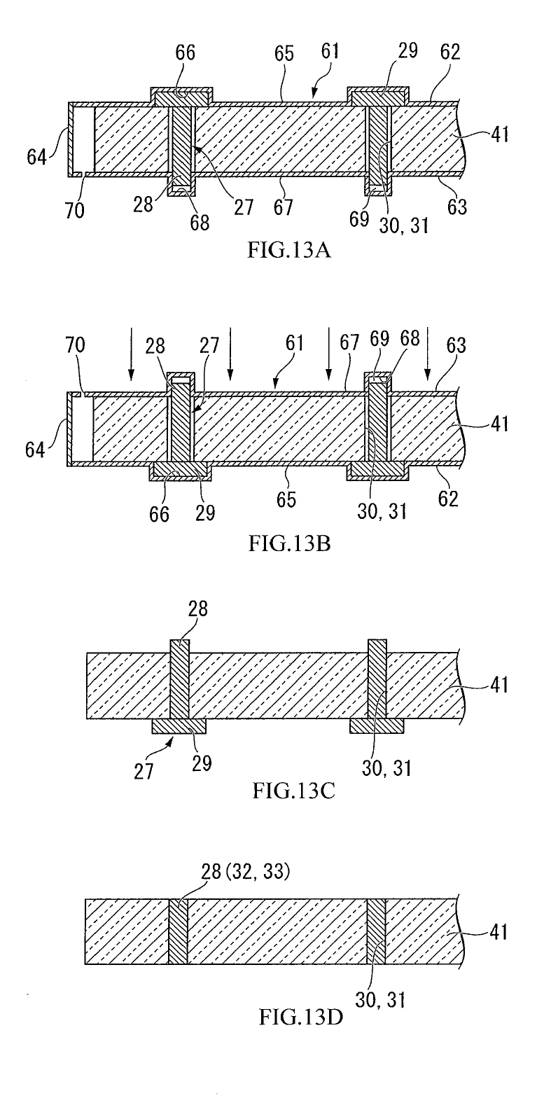

Subsequently, a step of inserting the core portions 28 into the through-holes 30 and 31 is performed (S13). FIGS. 13A to 13D are cross-sectional views of the base substrate wafer, illustrating a core portion insertion step, a welding step, and a polishing step.

As shown in FIG. 13A, the base substrate wafer 41 is placed on a pressurizing mold 63 of a welding mold 61 described later, and the core portions 28 of the rivet members 27 are inserted into the through-holes 30 and 31 from above. In this state, the base portions 29 of the rivet members 27 are brought into contact with the base substrate wafer 41, and the pressurizing mold 63 and a receiving mold 62, described later, of the welding mold 61 pinch the base substrate wafer 41 and the rivet members 27 therebetween, and this assembly is turned upside down as shown in FIG. 13B. The step of inserting the core portions 28 into the through-holes 30 and 31 is performed using an inserting machine.

At this time, in top view, the base portions 29 have a shape such that they are larger than the openings of the through-holes 30 and 31 and are capable of blocking the through-holes 30 and 31. Since the core portions 28 are connected to the base portions 29 to form the rivet members 27, they can be easily inserted into the through-holes 30 and 31, and the workability is improved.

### Welding Step

Subsequently, a step of heating the base substrate wafer 41 so that the base substrate wafer 41 is welded to the core portions 28 is performed (S14).

The welding step is performed by placing the base substrate wafers 41 one by one in the welding mold 61 made of a carbon material and having the receiving mold 62 disposed on the lower side of the base substrate wafer 41, the pressurizing mold 63 disposed on the upper side of the base substrate wafer 41, and side plates 64 provided on the lateral sides of the receiving mold 62 and the pressurizing mold 63, and pressing and heating the base substrate wafer 41.

The receiving mold 62 is a mold that holds the lower side of the base substrate wafer 41 and the rivet members 27. The receiving mold 62 has a shape such that it is larger than the base substrate wafer 41 in top view and it extends along the lower side (the lower side in FIG. 13B) of the base substrate wafer 41 in which the core portions 28 of rivet members 27 are inserted into the through-holes 30 and 31, and a part of each of the base portions 29 protrudes from the base substrate wafer 41.

The receiving mold 62 includes a receiving mold planar portion 65 that makes contact with the surface of the base substrate wafer 41 when holding the base substrate wafer 41 and receiving mold recess portions 66 which make contact with the base portions 29 and are recess portions corresponding to the base portions 29.

The receiving mold recess portions 66 are formed in alignment with the positions of the base portions 29 of the rivet members 27 provided on the base substrate wafer 41. The base portions 29 are fitted in the receiving mold recess portions 66, whereby the receiving mold 62 is able to hold the rivet members 27, and the rivet members 27 are prevented from being removed, and the core portions 28 are prevented from being displaced.

The pressurizing mold 63 is a mold that presses the base substrate wafer 41 and has the same top-view shape as the receiving mold 62. The pressurizing mold 63 has a shape such that it extends along the upper side (the upper side in FIG. 13B) of the base substrate wafer 41 in which the core portions 28 of rivet members 27 are inserted into the through-holes 30 and 31, and the tip ends of the core portions 28 protrude from the base substrate wafer 41.

The pressurizing mold 63 includes a pressurizing mold planar portion 67 that makes contact with the base substrate wafer 41 when pressing the upper side of the base substrate wafer 41 and pressurizing mold recess portions 68 through which the tip ends of the core portions 28 are inserted.

The pressurizing mold recess portions 68 are recess portions having a depth larger by about 0.2 mm than the height of the core portions 28 protruding from the base substrate wafer 41, and a gap 69 is formed between the tip ends of the core portions 28 and the bottom portions of the pressurizing mold recess portions 68.

Since the gap 69 is formed between the tip ends of the core portions 28 and the bottom portions of the pressurizing mold recess portions 68, the expanded portions of the core portions 28 due to heating can escape to the gap 69. Moreover, when the base substrate wafer 41 is pressed by the pressurizing mold 63, the pressure is not transmitted from the pressurizing mold 63 to the core portions 28, and the deformation or displacement of the core portions 28 can be prevented.

The pressurizing mold recess portions 68 are formed in alignment with the positions of the core portions 28 protruding from the base substrate wafer 41.

The pressurizing mold 63 includes a slit 70 which is provided at an end thereof so as to penetrate through the pressurizing mold 63. The slit 70 can be used as an escape hole for the air and surplus glass material of the base substrate wafer 41 when the base substrate wafer 41 is heated and pressed.

In the welding step, first, the base substrate wafer 41 and the rivet members 27 set on the welding mold 61 are placed on a mesh belt made of metal, and in such a state, they are inserted in a heating furnace and heated. Moreover, using a press machine or the like disposed in the heating furnace, the base substrate wafer 41 is pressed by the pressurizing mold 63 at a pressure of 30 to 50 g/cm², for example. The heating temperature is set to a temperature (for example, about 730° C. which is the softening point of soda-lime glass) equal to higher than the softening point of the base substrate wafer 41.

Moreover, the base substrate wafer 41 is pressed in the high temperature state, whereby the base substrate wafer 41 is moved to block the gaps between the core portions 28 and the through-holes 30 and 31, and the base substrate wafer 41 is welded to the core portions 28, so that the core portions 28 close the through-holes 30 and 31. By forming another convex or recess portion on the welding mold 61, a recess or convex portion may be formed on the base substrate wafer 41 when the base substrate wafer 41 is welded to the core portions 28.

Subsequently, the temperature is gradually decreased from about 730° C. which is the heating temperature during the welding step, thus cooling down the base substrate wafer 41 (S15). In this way, the base substrate wafer 41 is formed as shown in FIG. 13C in which the core portions 28 of the rivet members 27 block the through-holes 30 and 31.

Here, similarly to the through-hole forming mold 51, the welding mold 61 of the present embodiment is preferably formed using a material of which the open porosity is equal to or larger than 14% and the thermal expansion coefficient is equal to or larger than 4 ppm/° C.

By forming the welding mold 61 using the material having an open porosity equal to or larger than 14%, it is possible to suppress the occurrence of the bubble phenomenon, to maintain the desired disk shape of the base substrate wafer 41, and improve the demolding property of the welding mold 61.

Moreover, by forming the welding mold 61 using the material having a thermal expansion coefficient equal to or larger than 4 ppm/° C., it is possible to suppress strain occurring between the welding mold 61 and the base substrate wafer 41 resulting from the heating. In this way, it is possible to form the base substrate wafer 41 to a desired thickness and to an outer diameter with high accuracy. Moreover, since the stress applied from the welding mold 61 to the rivet members 27 due to the strain occurring between the welding mold 61 and the base substrate wafer 41 can be decreased, it is possible to suppress the base portions 29 fitted in the receiving mold recess portions 66 of the welding mold 61 from being moved towards the welding mold 61, so that the rivet members 27 are displaced from desired positions or tilted. As a result, since the positioning accuracy of the penetration electrodes 32 and 33 on the base substrate wafer 41 can be improved, it is possible to secure conduction between the penetration electrodes 32 and 33 and the outer electrodes 38 and 39 or the lead-out electrodes 36 and 37 which are connected to the penetration electrodes 32 and 33.

As a material satisfying such a condition, the welding mold 61 of the present embodiment is made of a material containing a boron nitride as its main component. Since the material containing a boron nitride as its main component is superior in oxidation resistance, even when the welding step is performed in an air atmosphere, it is possible to suppress the oxidation of the welding mold 61. In this way, it is possible to suppress the wetting property of the welding mold 61 and to maintain a demolding property. Moreover, the durability of the welding mold 61 can be improved, and the molding can be performed at a relatively high temperature. In addition, since the boron nitride is superior in mechanical processability, it is possible to secure the flatness (for example, within 30 μm) of the processed surface of the welding mold 61 and to secure the flatness of the base substrate wafer 41 molded so as to resemble the processed surface.

### Polishing Step

Subsequently, the protruding portions of the core portions 28 and the base portions 29 of the rivet members 27 are polished and removed (S16).

Polishing of the base portions 29 of the rivet members 27 and the core portions 28 is performed in accordance with a known method. As shown in FIG. 13D, the surface of the base substrate wafer 41 and the surfaces of the penetration electrodes 32 and 33 (the core portions 28) are substantially flush with each other. In this way, the penetration electrodes 32 and 33 are formed on the base substrate wafer 41. The base portions 29 and the protruding portions of the core portions 28 may not be removed but may be used as they are. For example, the base portions 29 and the protruding portions of the core portions 28 may be used as a heat dissipating plate or the like.

As described above, since the core portions 28 are welded to the base substrate wafer 41 by pressing and heating the base substrate 41 and the rivet members 27 with the welding mold 61, it is possible to form the penetration electrodes 32 and 33 using a material which does not contain binders of an organic material. Therefore, there is no decrease in volume resulting from the removal of the organic material unlike the case of inserting a glass frit between the through-holes 30 and 31 and the core portions 28, and it is possible to prevent the occurrence of recess portions around the penetration electrodes 32 and 33.

Subsequently, as shown in FIG. 10, a lead-out electrode forming step is performed by patterning a conductive material on the upper surface of the base substrate wafer 41 (S17). In this way, a step of manufacturing the base substrate wafer 41 ends.

Subsequently, at or around the same time as the manufacturing of the base substrate 2, a lid substrate wafer 42 later serving as the lid substrate 3 is manufactured (S30). In the step of manufacturing the lid substrate 3, first, a disk-shaped lid substrate wafer 42 later serving as the lid substrate 3 is formed. Specifically, soda-lime glass is polished to a predetermined thickness and cleaned, and then, the affected uppermost layer is removed by etching or the like (S31). Subsequently, a recess portion 3a for the cavity C is formed in the lid substrate wafer 42 by etching, press working, or the like (S32). After that, the bonding surface to be bonded to the base substrate wafer 41 is polished.

Subsequently, a bonding film 35 is formed on the bonding surface of the lid substrate wafer 42 to be bonded to the base substrate wafer 41 and the inner surface of the recess portion 3a by sputtering or the like (S33). In this way, by forming the bonding film 35 on the entire inner surface of the lid substrate wafer 42, the patterning of the bonding film 35 is not necessary, and the manufacturing cost can be reduced. In this case, the bonding film 35 may be formed on only the bonding surface of the lid substrate wafer 42 to be bonded to the base substrate wafer 41 by patterning after the deposition. Moreover, since the bonding surface is polished before the bonding film forming step (S33), the flatness of the surface of the bonding film 35 can be secured, and stable bonding with the base substrate wafer 41 can be achieved.

Subsequently, the plurality of piezoelectric vibrating reeds 4 manufactured by the piezoelectric vibrating reed manufacturing step (S1) is mounted on the lead-out electrodes 36 and 37 of the base substrate wafer 41 with bumps B made of gold or the like disposed therebetween. Then, the base substrate wafer 41 and the lid substrate wafer 42 manufactured by the manufacturing steps of the respective wafers 41 and 42 are superimposed onto each other. In this way, the mounted piezoelectric vibrating reeds 4 are accommodated in the cavity C surrounded by the recess portion 3a formed on the lid substrate wafer 42 and the base substrate wafer 41.

After the two substrate wafers 41 and 42 are superimposed onto each other, anodic bonding is achieved under a predetermined temperature atmosphere with application of a predetermined voltage in a state where the two superimposed wafers 41 and 42 are inserted into an anodic bonding machine (not shown) and the outer peripheral portions of the wafers are clamped by a holding mechanism (not shown). In this way, the piezoelectric vibrating reeds 4 can be sealed in the cavity C, and a wafer assembly 43 in which the base substrate wafer 41 and the lid substrate wafer 42 are bonded can be obtained.

Then, a pair of outer electrodes 38 and 39 is formed so as to be electrically connected to a pair of penetration electrodes 32 and 33, and the frequency of the piezoelectric vibrator 1 is adjusted finely. Moreover, a cutting step where the wafer assembly 43 is cut along the cutting line M to obtain small fragments is performed, and an inner electrical property test is conducted, whereby a piezoelectric vibrator 1 in which the piezoelectric vibrating reeds 4 are accommodated is formed.

As described above, in the present embodiment, the base substrate wafer 41 is hot-molded using the through-hole forming mold 51 and the welding mold 61 which are made of a material of which the open porosity is equal to or larger than 14% and the thermal expansion coefficient is equal to or larger than 4 ppm/° C.

According to this configuration, as described above, by setting the open porosity to be equal to or larger than 14%, it is possible to suppress the occurrence of the bubble phenomenon of the base substrate wafer 41 and to improve the demolding property of the through-hole forming mold 51 and the welding mold 61 after the hot-molding. In this way, it is possible to improve the yield of the piezoelectric vibrator 1. Moreover, since the amount of remaining outgas in the base substrate wafer 41 is reduced and the porosity of the base substrate wafer 41 can be decreased, it is possible to secure the airtightness of the cavity C of the piezoelectric vibrator 1 in which the base substrate wafer 41 and the recess portion 3a of the lid substrate wafer 42 are anodically bonded. Therefore, since the package 9 having excellent airtightness can be manufactured, it is possible to manufacture the piezoelectric vibrator 1 having excellent vibration characteristics and high reliability.

By setting the thermal expansion coefficient to be equal to or larger than 4 ppm/° C., it is possible to suppress the strain or the like occurring between the through-hole forming mold 51 and welding mold 61 and the base substrate wafer 41 resulting from heating. Thus, it is possible to form the base substrate wafer 41 into a desired shape and form the penetration electrodes 32 and 33 with desired positioning accuracy. In this way, since the conduction between the penetration electrodes 32 and 33 and the lead-out electrodes 36 and 37 and the outer electrodes 38 and 39 which are formed later can be secured, it is possible to provide the package 9 with excellent conduction between the inside and the outside of the cavity C.

### EXAMPLES

Hereinafter, examples of the present invention will be described.

The present inventor prepared a plurality of kinds of carbon materials (graphite) and boron nitrides (BN) having different compositions in order to choose a material to be used for the recess forming mold and the welding mold described above, produced sample molds for each of the plurality of kinds of materials, and performed hot-molding on the sample wafers using the respective sample molds. Although not shown, a disk-shaped wafer made of soda-lime glass similarly to the base substrate wafer was used as the sample wafers. Moreover, the sample molds had the same configuration as the through-hole forming mold 51, and included a receiving mold which was disposed on one surface side of the sample wafer so as to hold the sample wafer and a pressurizing mold which was disposed on the other surface side of the sample wafer and had a plurality of convex portions for forming through-holes on the sample wafer. Moreover, this test was conducted under the same conditions as used in the penetration hole forming step described above.

Table 1 shows materials of the molds used in this test, the compositions, thermal expansions coefficients, and porosities (open porosities and closed porosities) of the materials, and the processing results. In this test, three kinds of carbon materials and four kinds of boron nitrides were used.

TABLE 1

| | | | Thermal | | Open | Closed | Press |
|---|---|---|---|---|---|---|---|
| | | | Expansion | Porosity | Porosity | Porosity | Processing |
| | Material | Material Composition | Coefficient | (%) | (%) | (%) | Result |
| Example 1 | Graphite | Si, Fe, Ti, B, Ca, Mg, Al | 5.8 ppm | 17 | 15 | 2 | ◯ |
| Example 2 | Graphite | Si, Fe, Ti, B, Ca, Mg, Al | 6.8 ppm | 15 | 14 | 1 | ◯ |
| Comparative | Graphite | Si, Fe, Ti, B, Ca, Mg, Al | 7.1 ppm | 1-3 | 1-3 | — | X |
| Example 1 | | | | | | | |
| Example 3 | BN | BN % (70) Si₃N₄ (30) | 4.1 ppm | 20.5 | 20.3 | 0.2 | ◯ |
| Example 4 | BN | BN % (99.5 or higher) | −0.6 ppm | 29.2 | 29.2 | 0 | Δ |
| Comparative | BN | (Single BN-series): BN % (97) | −0.25 ppm | 13.6 | 4.6 | 9 | X |
| Example 2 | | | | | | | |
| Comparative | BN | (BN-Si₃N₄): BN % (30) | 3.0 ppm | 10.2 | 0.9 | 9.3 | X |
| Example 3 | | | | | | | |

As shown in Table 1, under the conditions of Examples 1 and 2, the sample wafers were molded in a favorable state. Specifically, the bubble phenomenon did not occur, and the sample wafers were maintained in the disk shape, and the through-holes were arranged at desired positioning accuracy (pitches). In addition, when the sample molds were removed from the sample wafers, the demolding properties were acceptable.

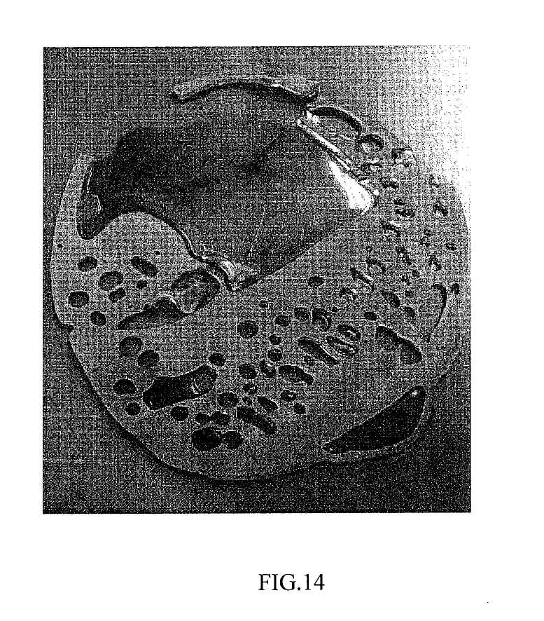

On the other hand, as shown in FIG. 14, in Comparative Example 1, the bubble phenomenon occurred in the sample wafer, and the sample wafer was not maintained in the disk shape. This is considered to be attributable to the fact that since the mold is filled with the outgas discharged from the sample wafer by the heating during the molding, there is no escape route for the outgas, and the outgas remains in the sample wafer as bubbles.

Under the conditions of Example 3, similarly to Examples 1 and 2, the sample wafer was molded in a favorable state.

On the other hand, in Comparative Examples 3 and 4, similarly to Comparative Example 1, the sample wafer was not maintained in a desired shape (see FIG. 14).

From these results, it can be understood that the open porosity of the sample mold (the through-hole forming mold 51 and the welding mold 61) of the present embodiment needs to be equal to or larger than 14%.

In contrast, in Example 4, the bubble phenomenon did not occur in the sample wafer, and the sample wafer was maintained in the disk shape. However, due to the strain between the sample wafer and the sample mold, the thickness or the outer diameter of the sample wafer deviated slightly, and the positioning accuracy of the through-holes on the sample wafer decreased.

From these results, it can be understood that in order to improve the external dimensions of the sample wafer or the positioning accuracy of the through-holes, it is preferable to produce the sample mold using a material of which the thermal expansion coefficient is close to that of the glass material, and specifically, it is preferable to produce the sample mold using a material of which the thermal expansion coefficient is equal to or larger than 4 ppm/° C.

However, when the hot-molding is performed under an air atmosphere using a sample mold made of graphite, the air in a heating furnace oxidizes the sample mold, and thus, the durability of the sample mold may decrease. Moreover, the wetting of the sample mold by the base substrate increases, and thus the demolding property of the sample mold may decrease. Even when the hot-molding is performed in the inert gas atmosphere, air or vapor may enter through the inlet and outlet of the heating furnace. In this case, the same problems as those occurring in an air atmosphere may occur.

Table 2 shows the oxidation reaction starting temperature of graphite under different molding atmospheres or reaction targets.

TABLE 2

| Atmosphere or | | |
|---|---|---|
| Reaction Target | Reaction Temperature (° C.) | Reaction Product |
| Air | 400 | Oxide |
| Vapor | 700 | Oxide |

As shown in Table 2, a sample mold made of graphite begins oxidation reaction at 400° C. under an air atmosphere and at 700° C. under the vapor atmosphere.

From the above, it can be understood that when a mold made of graphite (the through-hole forming mold 51) is used at a relatively high temperature as in the case of the penetration hole forming step, it is preferable to perform the processing under an inert gas atmosphere such as a nitrogen atmosphere. On the other hand, when a mold made of BN (the welding mold 61) is used as in the case of the welding step, the processing can be performed under an air atmosphere. In general, when the hot-molding is performed at a temperature equal to or higher than 600° C. under an air atmosphere, it is preferable to use a mold made of BN.

However, when it is necessary to secure the durability for mass production, the through-hole forming mold 51 may be produced using BN having excellent abrasion resistance rather than graphite and perform the penetration hole forming step.

On the other hand, in the case of low-volume production or the like, the welding mold 61 may be produced using graphite rather than BN. In this case, as described above, although graphite causes an oxidation reaction under an air atmosphere, since the graphite is cheaper than BN, the manufacturing cost of the piezoelectric vibrator 1 produced using the welding mold 61 made of graphite can be suppressed to be equal to the manufacturing cost of the piezoelectric vibrator 1 produced using the welding mold 61 made of BN.

### Second Embodiment

Next, the second embodiment of the present invention will be described. In the following description, the same constituent elements as those in the first embodiment will be denoted by the same reference numerals, and description thereof will be omitted and only the configurations different from those of the first embodiment will be described.

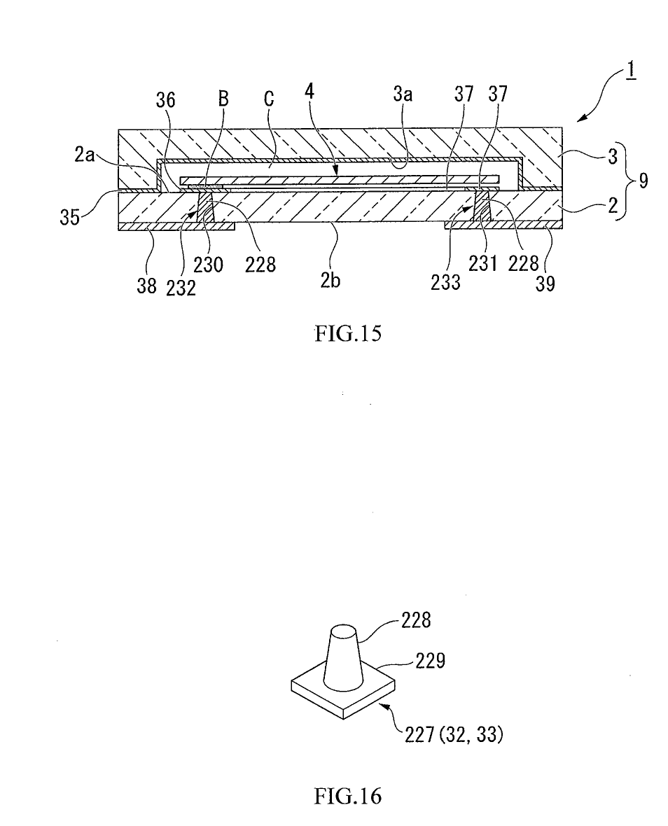

As shown in FIG. 15, a piezoelectric vibrator 201 of the second embodiment has a configuration in which core portions 228 later serving as the penetration electrodes 32 and 33 have a truncated conical shape, and through-holes 230 and 231 have a tapered inner circumferential surface.

FIG. 16 is a perspective view of a rivet member according to the second embodiment.

As shown in FIG. 16, the core portions 228 form rivet members 227 together with base portions 229 in the course of the manufacturing process similarly to the first embodiment.

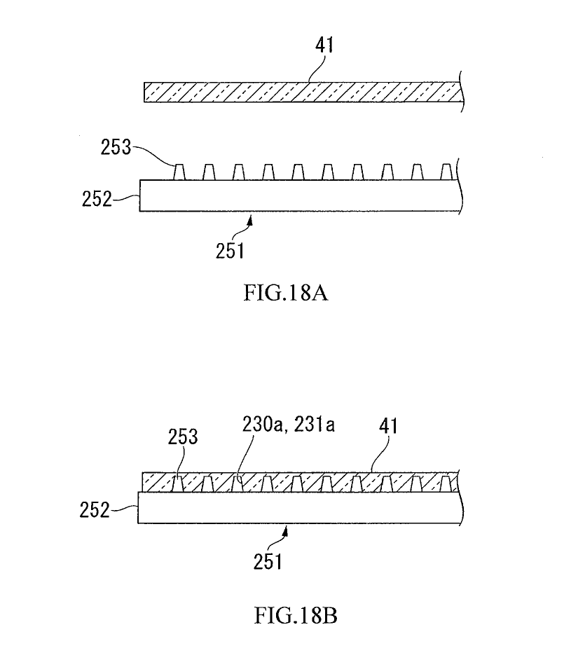

Moreover, the through-holes 230 and 231 are formed in the base substrate wafer 41 as recess portions 230a and 231a (see FIG. 18B) in the course of the manufacturing process. Moreover, the base substrate wafer 41 on the bottom side of the recess portions 230a and 231a is polished and removed in a later step, and the through-holes 230 and 231 become penetration holes that penetrate through the base substrate wafer 41 as shown in FIG. 15.

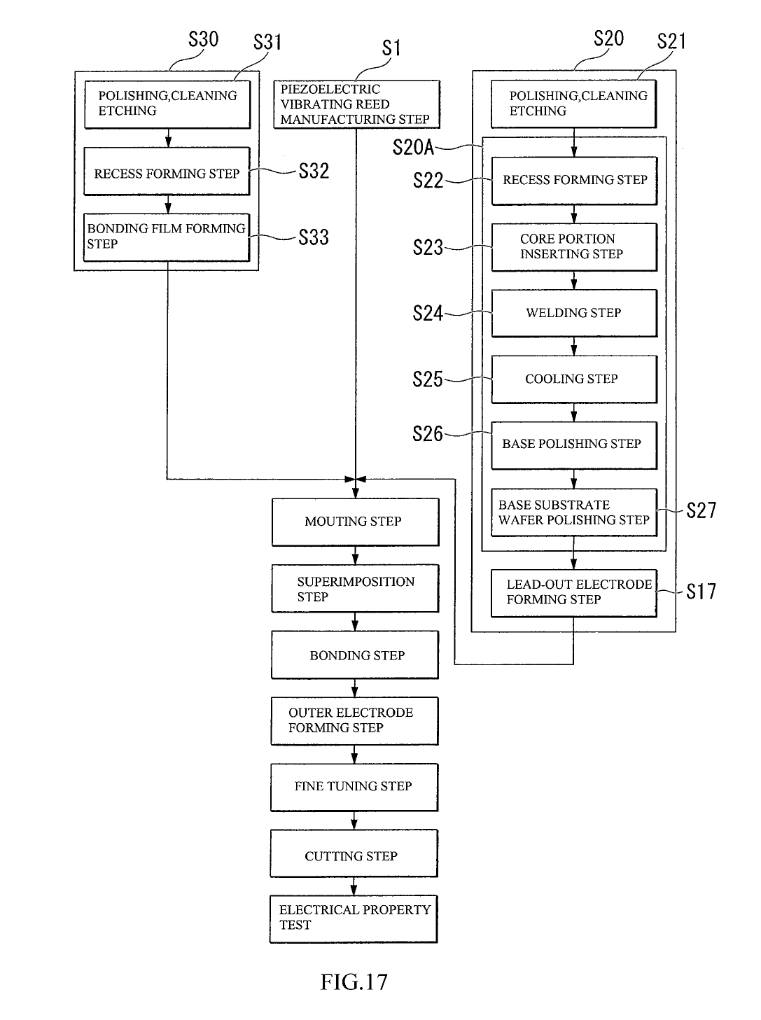

Next, a method of manufacturing the piezoelectric vibrator of the second embodiment will be described with reference to a flowchart shown in FIG. 17. The description of the same steps as those in the first embodiment will be omitted.

First, as shown in FIG. 17, a step of manufacturing the base substrate wafer 41 later serving as the base substrate 2 is performed (S20). Specifically, similarly to the first embodiment, the base substrate wafer 41 is manufactured (S21), and subsequently, a penetration electrode forming step of forming the penetration electrodes 32 and 33 on the base substrate wafer 41 is performed (S20A).

### Recess Forming Step

Subsequently, the recess portions 230a and 231a are formed on the base substrate wafer 41. FIGS. 18A and 18B are cross-sectional views of the base substrate wafer, illustrating the recess forming step.

The recess portions 230a and 231a are formed by pressing and heating the base substrate wafer 41 with a recess forming mold (shaping mold) 251 made of a material containing a carbon material as its main components as shown in FIGS. 18A and 18B.

The recess forming mold 251 includes a planar portion 252 and convex portions 253 similarly to the through-hole forming mold 51 (see FIGS. 18A and 18B) of the first embodiment. The convex portions 253 have a truncated conical shape corresponding to the through-holes 230 and 231 and have a height lower than the thickness of the base substrate wafer 41.

As shown in FIG. 18B, in the recess forming step, similarly to the penetration hole forming step of the first embodiment, the base substrate wafer 41 is placed on the recess forming mold 251. Then, the base substrate wafer 41 and the recess forming mold 251 are placed in a heating furnace maintained under an inert gas atmosphere such as a nitrogen atmosphere with pressure applied in a high temperature state of about 900° C. At that time, the convex portions 253 of the recess forming mold 251 do not penetrate through the base substrate wafer 41, and the recess portions 230a and 231a resembling the shape of the convex portions 253 of the recess forming mold 251 are formed on the base substrate wafer 41. The recess portions 230a and 231a are formed so as to be larger, for example, by 20 to 30 μm than the outer shape of the core portions 228. Subsequently, the temperature is gradually decreased to cool down the base substrate wafer 41.

In the second embodiment, since the recess forming mold 251 having the low-height truncated conical convex portions 253 is used, the molding can be performed easily as compared to the through-hole forming mold 51 having the high-height cylindrical convex portions 53 of the first embodiment. Since the recess portions 230a and 231a have a tapered shape, the recess forming mold 251 can be easily demolded in the recess forming step.

The recess forming step can be performed easily as compared to the penetration hole forming step of the first embodiment since it is not necessary to form the through-holes 30 and 31 (see FIG. 12B) penetrating the base substrate wafer 41 as in the case of the first embodiment.

### Core Portion Insertion Step

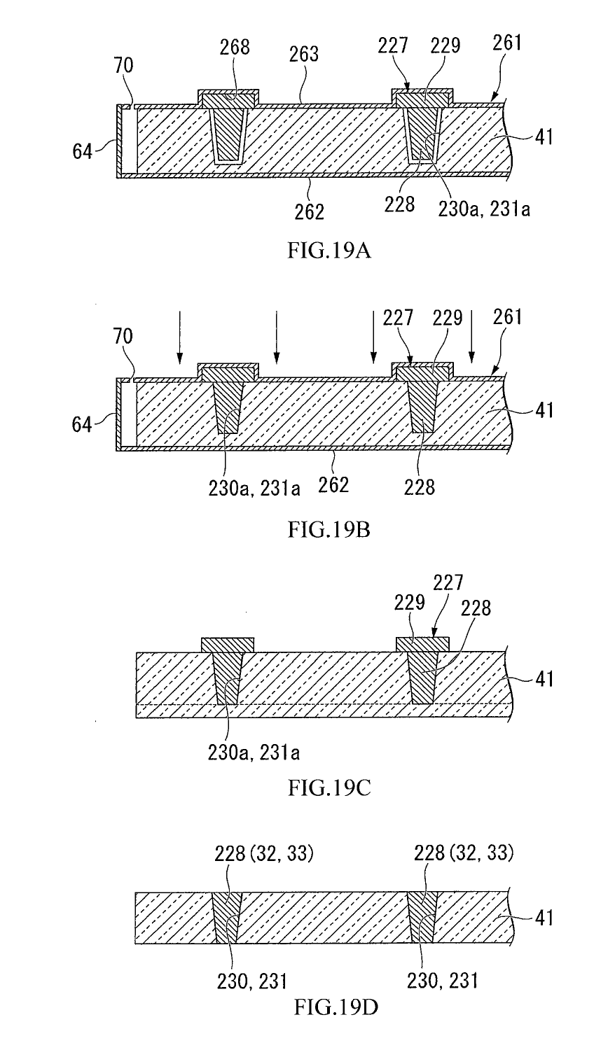

Subsequently, a step of inserting the core portions 228 into the recess portions 230a and 231a is performed (S23). FIGS. 19A to 19D are cross-sectional views of the base substrate wafer, illustrating the core portion insertion step and a welding step described later.

As shown in FIGS. 19A to 19D, the base substrate wafer 41 is placed with the recess portions 230a and 231a disposed on the upper side, the core portions 228 are inserted from above, and the base portions 229 are brought into contact with the base substrate wafer 41. At that time, since the core portions 228 have a truncated conical shape and the recess portions 230a and 231a have a tapered surface, the core portions 228 can be inserted easily.

### Welding Step and Cooling Step

Subsequently, a step of welding the base substrate wafer 41 to the core portions 228 using a welding mold 261 having side plates 64, a pressurizing mold 263, and a receiving mold 262 is performed (S24). Specifically, the pressurizing mold 263 is placed above the base substrate wafer 41 in which the rivet members 227 are inserted. The pressurizing mold 263 has pressurizing mold recess portions 268 which correspond to the base portions 229 of the rivet members 227, and the base portions 229 are inserted into the pressurizing mold recess portions 268. The base portions 229 and the bottom portions of the pressurizing mold recess portions 268 are not separated from each other, so that the base portions 229 are pressed by the pressurizing mold 263 at the time of the pressing during the welding step.

Moreover, the planar receiving mold 262 is placed below the base substrate wafer 41 so that the base substrate wafer 41 is held thereon. The welding mold 261 is formed of a material containing a boron nitride as its main components similarly to the welding mold 61 (see FIGS. 13A to 13D) of the first embodiment.

As shown in FIG. 19B, similarly to the first embodiment, the base substrate wafer 41 is pressed in the high temperature state, whereby the base substrate wafer 41 is moved to block the gaps between the core portions 228 and the recess portions 230a and 231a, and the base substrate wafer 41 is welded to the core portions 228. Even when one set of ends of the core portions 228 are pressed from the pressurizing mold 263, since the other ends are inserted into the recess portions 230a and 231a of the base substrate wafer 41, the one set of ends are not pressed. Thus, the expanded portions of the core portions 228 due to heating can escape, and the deformation or damage of the core portions 228 can be prevented. Moreover, it is possible to prevent the occurrence of cracks or voids in the base substrate wafer 41 due to the deformation or displacement of the core portions 228. Subsequently, a step of cooling down the base substrate wafer 41 is performed similarly to the first embodiment (S25).

### Base Portion Polishing Step and Base Substrate Wafer Polishing Step

Subsequently, similarly to the second embodiment, the base portions 229 of the rivet members 227 shown in FIG. 19C are polished and removed (S26).

At around the same time as the base portion polishing step, the base substrate wafer 41 is polished so that the recess portions 230a and 231a become the penetration holes (S27). In the base substrate wafer polishing step, the base substrate wafer 41 on the bottom side of the recess portions 230a and 231a is polished in accordance with the known method. Moreover, as shown in FIG. 18D, the recess portions 230a and 231a are penetrated to form the through-holes 230 and 231, and the ends of the core portions 228 are exposed from the base substrate wafer 41.

Subsequently, the steps subsequent to the base portion polishing step and the base substrate wafer polishing step are performed similarly to the first embodiment, and a package (piezoelectric vibrator 201) is manufactured.

As described above, according to the second embodiment, the same effects as the first embodiment can be obtained. In the welding step, since the base substrate wafer 41 is pressed in a state where the core portions 228 are inserted into the recess portions 230a and 231a, the ends of the core portions 228 close to the pressurizing mold 263 are pressed. However, since the other ends of the core portions 228 are not pressed, it is possible to prevent a damage to the core portions 228.

Moreover, since the core portions 228 have a truncated conical shape and the recess portions 230a and 231a have a tapered surface, the core portions 228 can be easily inserted into the recess portions 230a and 231a.

Furthermore, since the recess portions 230a and 231a have a tapered shape, the recess forming mold 251 can be easily demolded in the recess forming step.

### Oscillator

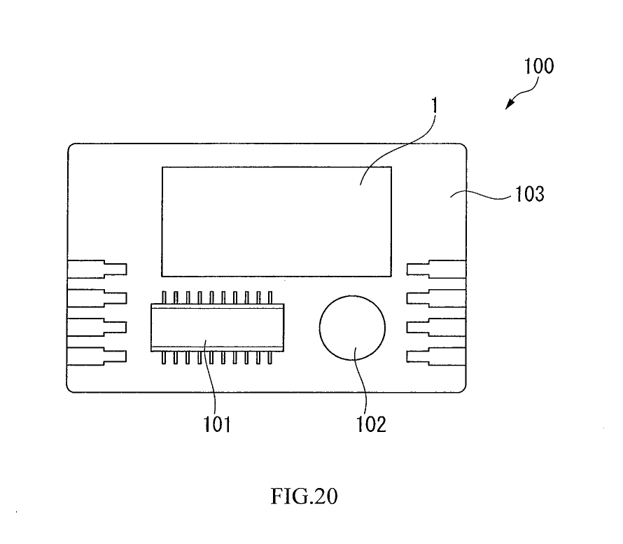

Next, an oscillator according to another embodiment of the invention will be described with reference to FIG. 20.

In an oscillator 100 according to the present embodiment, the piezoelectric vibrator 1 is used as an oscillating piece electrically connected to an integrated circuit 101, as shown in FIG. 20. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 4 in the piezoelectric vibrator 1 vibrates. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a clock.

As described above, according to the oscillator 100 of the present embodiment, since the oscillator includes the piezoelectric vibrator 1 in which the base substrate 2 and the lid substrate 3 are reliably anodically bonded, and reliable airtightness in the cavity C is secured, it is possible to achieve an improvement in the operational reliability and high quality of the oscillator 100 itself which provides stable conductivity. In addition to this, it is possible to obtain a highly accurate frequency signal which is stable over a long period of time.

### Electronic Apparatus

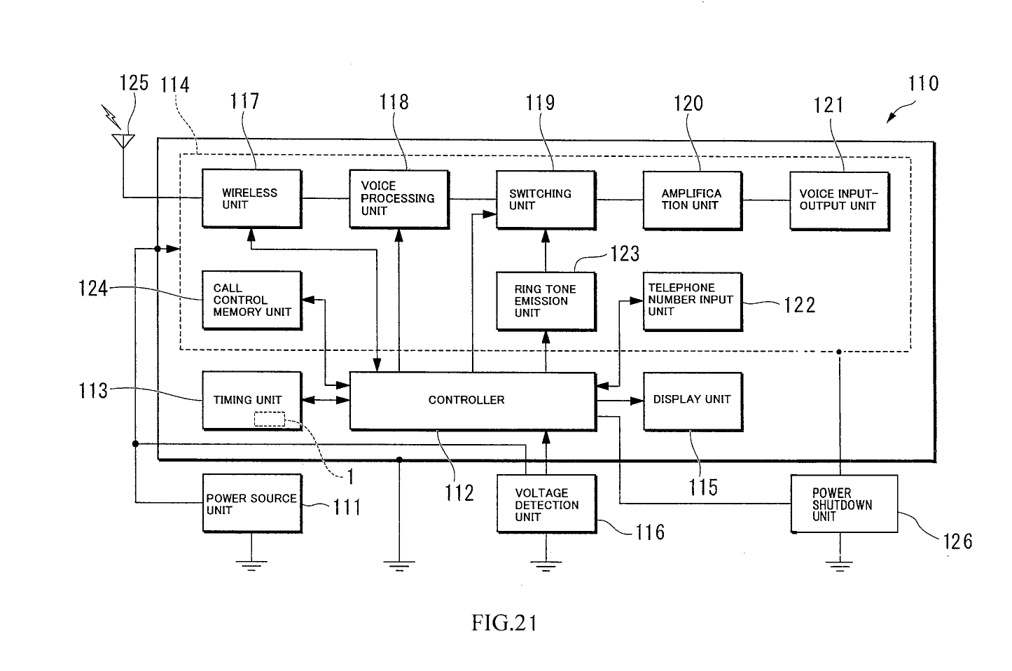

Next, an electronic apparatus according to another embodiment of the invention will be described with reference to FIG. 21. In addition, a portable information device 110 including the piezoelectric vibrator 1 will be described as an example of an electronic apparatus.

The portable information device 110 according to the present embodiment is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built into an inner portion of the band. However, the portable information device 110 is very small and light compared with a mobile phone in the related art.

Next, the configuration of the portable information device 110 according to the present embodiment will be described. As shown in FIG. 21, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs measuring of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, an interface circuit and the like therein, and the piezoelectric vibrator 1. When a voltage is applied to the piezoelectric vibrator 1, the piezoelectric vibrating reed 4 vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound louder or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as a lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, according to the portable information device 110 of the present embodiment, since the portable information device includes the high-quality piezoelectric vibrator 1 having improved yield in which the base substrate 2 and the lid substrate 3 are reliably anodically bonded, and reliable airtightness in the cavity C is secured, it is possible to achieve an improvement in the operational reliability and high quality of the portable information device 110 itself which provides stable conductivity. In addition to this, it is possible to display highly accurate clock information which is stable over a long period of time.

### Radio-Controlled Timepiece

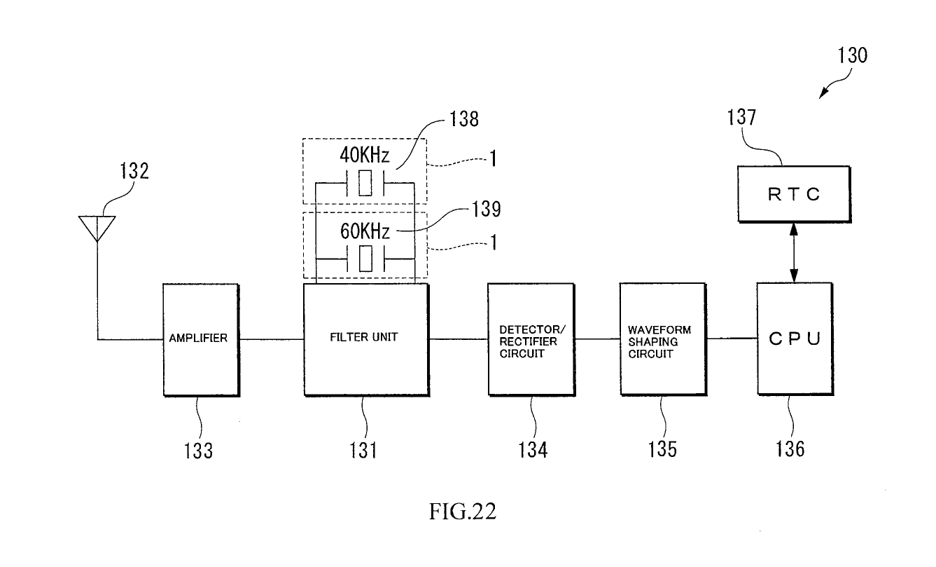

Next, a radio-controlled timepiece according to still another embodiment of the invention will be described with reference to FIG. 22.

As shown in FIG. 22, a radio-controlled timepiece 130 according to the present embodiment includes the piezoelectric vibrators 1 electrically connected to a filter section 131. The radio-controlled timepiece 130 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area in Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1. In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134. Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, according to the radio-controlled timepiece 130 of the present embodiment, since the radio-controlled timepiece includes the high-quality piezoelectric vibrator 1 having improved yield in which the base substrate 2 and the lid substrate 3 are reliably anodically bonded, and reliable airtightness in the cavity C is secured, it is possible to achieve an improvement in the operational reliability and high quality of the radio-controlled timepiece 130 itself which provides stable conductivity. In addition to this, it is possible to measure time highly accurately and stably over a long period of time.

It should be noted that the technical scope of the present invention is not limited to the embodiments above, and the embodiments can be modified in various ways without departing from the spirit of the present invention and such modifications are also within the technical scope of the present invention. That is, specific materials and layer structures exemplified in the embodiments are only examples and can be appropriately changed.

In the above-described embodiment, the through-holes 30 and 31 were formed by hot-molding the base substrate wafer 41 with the through-hole forming mold 51. Besides this, the through-holes 30 and 31 may be formed in the base substrate wafer 41 by a sand blast method or the like.

The penetration electrodes may be formed by inserting the core portions 28 into the through-holes 30 and 31, inserting the glass frits therein, and baking the glass frit.

The present embodiment may be applied to the case of forming the recess portions 3a for the cavity C in the lid substrate wafer 42 in addition to the step of forming the penetration electrodes 32 and 33.

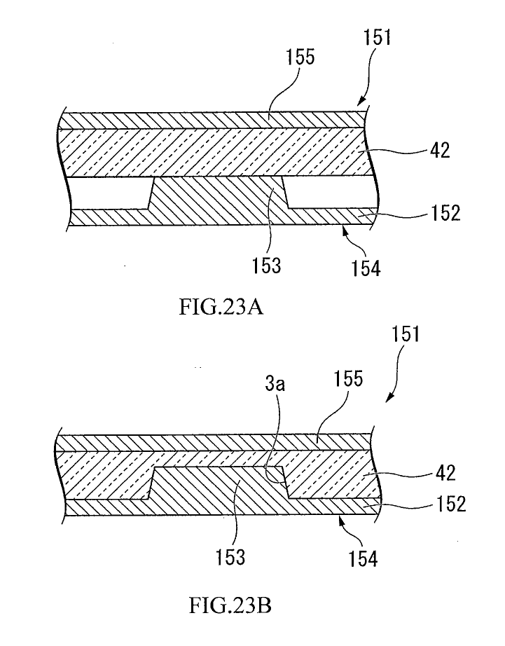

Specifically, as shown in FIG. 23A, a cavity forming mold (shaping mold) 151 is disposed so as to vertically pinch the lid substrate wafer 42 (from the upper and lower sides in FIGS. 23A and 23B). The cavity forming mold 151 includes a planar portion 152 which is disposed on the lower side of the lid substrate wafer 42, a pressurizing mold 154 having convex portions 153 which are formed on one surface of the planar portion 152 so as to correspond to the recess portions 3a, and a receiving mold 155 which is disposed on the upper side of the lid substrate wafer 42. The cavity forming mold 151 is formed of a carbon material or a boron nitride of which the open porosity is equal to or larger than 14%.

As shown in FIG. 23B, the pressurizing mold 154 of the cavity forming mold 151 is placed with the convex portions 153 positioned on the upper side, and the lid substrate wafer 42 is placed thereon. Then, this assembly is placed in a heating furnace maintained under an inert gas atmosphere and pressed and heated by the pressurizing mold 154, whereby the recess portions 3a resembling the shape of the convex portions 153 of the cavity forming mold 151 can be formed on the lid substrate wafer 42.

Although in the above embodiments, hot-molding was performed on the substrate wafers 41 and 42 made of soda-lime glass, the present invention is not limited to this, and the hot-molding may be performed on a wafer made of borosilicate glass (softening point: about 820° C.).

What is claimed is:

1. A method for producing piezoelectric vibrators, comprising:
(a) defining a plurality of first substrates on a first wafer and a plurality of second substrates on a second wafer;
(b) forming a pair of holes in a respective at least some of the first substrates on the first wafer;
(c) placing a conductive rivet in a respective at least some of the holes;
(d) press-fusing the first wafer in a mold to hermetically closing the at least some of the holes with the conductive rivet therein, wherein the mold has at least one of the following physical properties:
(i) an open porosity equal to or larger than about 14%; and
(ii) a thermal expansion coefficient equal to or larger than about 4 ppm/° C.;
(e) hermetically bonding the first and second wafers such that at least some of the first substrates substantially coincide respectively with at least some of the corresponding second substrates, wherein a piezoelectric vibrating strip is secured in a respective pairs of at least some of coinciding first and second substrates; and
(f) cutting off cutting off a respective at least some of packages made of coinciding first and second substrates.

2. The method according to claim 1, wherein forming a pair of holes in a respective at least some of the first substrates comprises pressing a die with a plurality projections onto the first wafer to form through-holes in the first wafer.

3. The method according to claim 2, wherein each projection has cross-sections which become smaller towards its tip.

4. The method according to claim 2, wherein the through-hole has a cross-section about 20 μm to about 30 μm larger than a cross-section of the conductive rivet.

5. The method according to claim 2, wherein the die has at least one of the following physical properties:
(i) an open porosity equal to or larger than about 14%; and
(ii) a thermal expansion coefficient equal to or larger than about 4 ppm/° C.

6. The method according to claim 2, wherein the die is made mainly of carbon.

7. The method according to claim 2, wherein pressing a die with a plurality projections onto the first wafer comprises pressing a die with a plurality projections onto the first wafer at a temperature about 900° C. in an inert gas atmosphere.

8. The method according to claim 1, wherein the mold comprises a pressing mold and a receiving mold having recesses aligned between the pressing and receiving molds to receive heads and tips of the conductive rivets therein.

9. The method according to claim 1, wherein the mode is made mainly of boron nitride.

10. The method according to claim 1, wherein press-fusing the first wafer in a mold comprises compressing the first wafer under a pressure of about 30-about 50 g/cm² at a temperature equal to or higher than about 750° C.

11. The method according to claim 1, further comprising grinding at least one end of the conductive rivet.

12. The method according to claim 1, wherein forming a pair of holes in a respective at least some of the first substrates comprises pressing a die with a plurality projections onto the first wafer to form the holes with a bottom in the first wafer.

13. The method according to claim 12, further comprising grinding at least one surface of the first wafer to expose both ends of the conductive rivet in both surfaces of the first wafer.

14. A molding die for pressing a glass wafer inside, having at least one of the following physical properties:
(i) an open porosity equal to or larger than about 14%; and
(ii) a thermal expansion coefficient equal to or larger than about 4 ppm/° C.

15. The molding die according to claim 14, wherein the molding die is made mainly of carbon.

16. The molding die according to claim 14, wherein the molding die is made mainly of boron nitride.
